(19) United States
(12) Patent Application Publication
(10) Pub. No.: US 2021/0166967 A1
(43) Pub. Date: Jun. 3, 2021

(54) SUBSTRATE POLISHING APPARATUS AND SUBSTRATE POLISHING METHOD

(71) Applicant: EBARA CORPORATION, Tokyo (JP)

(72) Inventors: Akira FUKUNAGA, Tokyo (JP); Katsuhide WATANABE, Tokyo (JP); Itsuki KOBATA, Tokyo (JP); Manabu TSUJIMURA, Tokyo (JP)

(21) Appl. No.: 16/616,549

(22) PCT Filed: May 2, 2018
(86) PCT No.: PCT/JP2018/017517

§ 371 Date: Nov. 25, 2019

(30) Foreign Application Priority Data
May 26, 2017 (JP) 2017-104585

(51) Int. Cl. H01L 21/768; H01L 21/321; H01L 21/66; B24B 37/04; B24B 37/005; B24B 37/015

(52) U.S. Cl. CPC H01L 21/7684; H01L 21/3212; H01L 22/12; B24B 37/015; B24B 37/005; B24B 37/0056; B24B 37/044

(57) ABSTRACT

To planarize a substrate having irregularities on its surface. Provided is a method of chemical mechanical polishing of a substrate. The method includes the step of polishing the substrate using a processing solution, and the step of changing concentration of an effective component in the processing solution, which contributes to the polishing of the substrate.

### TECHNICAL FIELD

The invention relates to a substrate polishing apparatus and a substrate polishing method.

### BACKGROUND ART

Processing units have recently been used to provide a variety of processing to workpiece (which include, for example, substrates, such as semiconductor substrates, and a variety of films formed on the surfaces of substrates). An example of the processing units is a CMP (Chemical Mechanical Polishing) apparatus for performing the polishing processing of to-be-processed objects, and other like processing.

### CITATION LIST

### Patent Literature

PTL 1: Japanese Unexamined Patent Application Publication (Kokai) No. 2005-235901

### SUMMARY OF INVENTION

### Technical Problem

Accuracy desired in each process of fabrication of latest semiconductor devices has already reached the order of several nanometers. The same trend is happening to the CMP apparatus. At the same time, the high integration of semiconductor integrated circuits accelerates the miniaturization and multi-layering of the semiconductor integrated circuits. When a miniaturized multilevel interconnect structure is created, even slight roughness on the interconnect surface should not be neglected. Otherwise, the irregularities on the surface might cause various defects. In this light, planarization in the order of several nanometers is desired in the polishing process in fabrication of semiconductor devices, and controllability in substrate polishing is also desired at an atomic layer level.

### Solution to Problem

[Mode 1] Mode 1 provides a method of chemical mechanical polishing of a substrate. The method includes the step of polishing the substrate using a processing solution and the step of changing concentration of an effective component in the processing solution, which contributes to the polishing of the substrate.
[Mode 2] The method described in the Mode 1 according to Mode 2 is designed so that the effective component in the processing solution contains at least one of (1) a component that oxidizes a layer to be polished of the substrate, (2) a component that dissolves the layer to be polished of the substrate, and (3) a component that exfoliates the layer to be polished of the substrate.
[Mode 3] The method described in the Mode 1 or 2 according to Mode 3 further includes the step of measuring thickness of the layer to be polished of the substrate, and based on the measured thickness of the layer to be polished of the substrate, the concentration of the effective component in the processing solution is changed.
[Mode 4] The method described in the Mode 1 or 2 according to Mode 4 further includes the step of measuring pH in the processing solution, and based on the measured pH in the processing solution, the concentration of the effective component in the processing solution is changed.
[Mode 5] The method described in the Mode 1 or 2 according to Mode 5 is designed so that the processing solution contains abrasive particles. The method includes the step of measuring abrasive particle concentration in the processing solution. Based on the measured abrasive particle concentration, the concentration of the effective component in the processing solution is changed.
[Mode 6] The method described in any one of the Modes 1 to 5 according to Mode 6 is designed so that the concentration of the effective component in the processing solution is changed by attenuating the processing solution with pure water.
[Mode 7] The method described in any one of the Modes 1, 2 and 4 according to Mode 7 is designed so that the processing solution contains an oxidizing component. The concentration of the oxidizing component in the processing solution is effectively changed by adding a reductant for reducing an oxidation effect of the processing solution.
[Mode 8] The method described in any one of the Modes 1, 2 and 4 according to Mode 8 is designed so that the processing solution contains acid as a dissolution component. The concentration of the dissolution component is changed by adding an alkaline agent into the processing solution.
[Mode 9] The method described in any one of the Modes 1, 2 and 4 according to Mode 9 is designed so that the processing solution contains alkali as a dissolution component. The concentration of the dissolution component is changed by adding acid into the processing solution.
[Mode 10] Mode 10 provides a method of chemical mechanical polishing of a substrate. The method includes the step of polishing the substrate using a processing solution and the step of changing temperature of the processing solution during the polishing of the substrate.
[Mode 11] The method described in the Mode 10 according to Mode 11 further includes the step of measuring thickness of a layer to be polished of the substrate, and based on the measured thickness of the layer to be polished of the substrate, the temperature of the processing solution is changed.
[Mode 12] Mode 12 provides a method of chemical mechanical polishing of a plurality of substrates of the same kind. The method includes the step of polishing a first substrate using a first processing solution and the step of polishing a second substrate using a second processing solution. The second processing solution differs from the first processing solution in concentration of an effective component contained in the processing solution, which contributes to the polishing of the substrate.
[Mode 13] Mode 13 provides a method for removing a metal layer formed on a substrate. The method includes the step of intermittently supplying the metal layer of the substrate with an oxidizing agent and/or a complexation agent and thus forming a brittle reaction layer on a surface of the metal layer, and the step of polishing and removing the brittle reaction layer with a pad pressed against the brittle reaction layer in the presence of the processing solution.
[Mode 14] The method described in the Mode 13 according to Mode 14 further includes the step of polishing the substrate with the pad pressed against the substrate in the presence of pure water.
[Mode 15] The method described in the Mode 13 or 14 according to Mode 15 includes the step of supplying the oxidizing agent and/or the complexation agent onto the pad while the substrate and the pad are out of contact with each other, and then bringing the substrate and the pad into contact with each other.
[Mode 16] The method described in the Mode 13 or 14 according to Mode 16 includes the step of intermittently supplying the oxidizing agent and/or the complexation agent from direction of the pad toward the substrate.
[Mode 17] The method described in the Mode 16 according to Mode 17 includes the step of supplying a first processing solution containing an oxidizing agent and/or a complexation agent from direction of the pad toward the substrate, and the step of supplying a second processing solution containing a different component from the first processing solution from above the pad toward the pad.
[Mode 18] The method described in the Mode 17 according to Mode 18 is designed so that the processing solution contains a reductant.
[Mode 19] Mode 19 provides a method for removing a metal layer formed on a substrate. The method includes the step of supplying an electrolyte solution to the metal layer of the substrate, the step of supplying electric current to the metal layer of the substrate through the electrolyte solution, and the step of polishing the substrate with a pad pressed against the substrate.
[Mode 20] The method described in any one of the Modes 13 to 19 according to Mode 20 includes the step of changing a supply amount of the oxidizing agent and/or the complexation agent during the removal of the metal layer.
[Mode 21] The method described in the Mode 19 according to Mode 21 includes the step of changing a magnitude of the electric current that is supplied to the substrate during the polishing of the substrate.
[Mode 22] Any one of the Modes 13 to 21 according to Mode 22 includes the step of changing a duration when the pad is pressed against the substrate during the removal of the metal layer.
[Mode 23] Any one of the Modes 13 to 21 according to Mode 23 is designed so that the metal layer includes at least one from a group consisting of aluminum, tungsten, copper, ruthenium, and cobalt.
[Mode 24] Mode 24 provides a method for removing a silicon dioxide layer that is formed on a substrate. The method includes the step of supplying an adsorptive surface-active agent to the silicon dioxide layer and thus forming a protective layer on a surface of the silicon dioxide layer, the step of polishing the protective layer with a pad pressed against the protective layer in the presence of a processing solution and thus removing the silicon dioxide layer, and the step of intermittently supplying the pad with an additive that facilitates adsorption of abrasive particles onto the pad.

### BRIEF DESCRIPTION OF DRAWINGS

FIG. 1 is a perspective view schematically showing a substrate polishing apparatus according to one embodiment.

FIG. 2 is a lateral view schematically showing the substrate polishing apparatus according to one embodiment.

FIG. 3 is a lateral view schematically showing the substrate polishing apparatus according to one embodiment.

FIG. 4A is a top view schematically showing the substrate polishing apparatus according to one embodiment.

FIG. 4B is a lateral view of a top ring that holds a reaction solution bath and a substrate, as viewed from direction of arrow 4B shown in FIG. 4A.

FIG. 5A is a top view schematically showing the substrate polishing apparatus according to one embodiment.

FIG. 5B is a lateral view of the top ring that holds an electrolyte solution bath and the substrate, as viewed from direction of arrow 5B shown in FIG. 5A.

FIG. 6 is a schematic flowchart showing a polishing method according to one embodiment.

FIG. 7 is a schematic flowchart showing a method of removing a metal layer that is formed on a surface of the substrate according to one embodiment.

FIG. 8 show an example of substrate planarization by polishing according to one embodiment.

FIG. 9 show an example of substrate planarization by polishing according to one embodiment.

FIG. 10 show an example of substrate planarization by polishing according to one embodiment.

FIG. 11 show an example of a planarization process in embedment of copper interconnects through Chemical Mechanical Polishing.

### DESCRIPTION OF EMBODIMENTS

The following description explains embodiments of a substrate polishing apparatus and a substrate polishing method according to the present invention with reference to the attached drawings. In the attached drawings, identical or similar elements will be provided with identical or similar reference marks. Explanations overlapped among the identical or similar elements in the description of the embodiments are sometimes omitted. Each feature discussed in each of the embodiments is applicable to the other embodiments as long as there is no discrepancy.

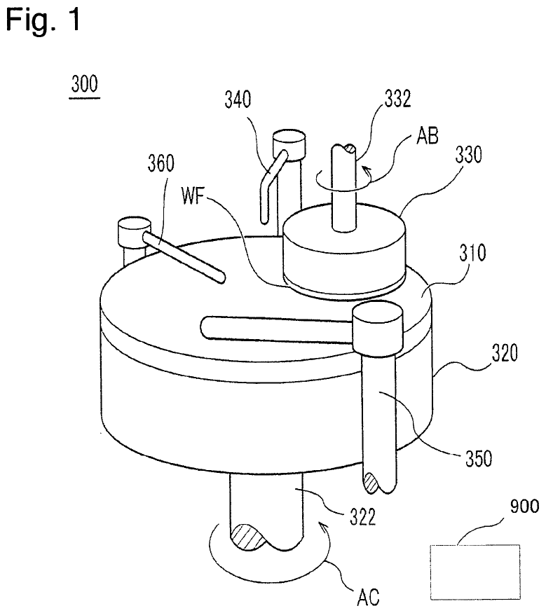

FIG. 1 is a perspective view schematically showing a substrate polishing apparatus 300 according to one embodiment. The substrate polishing apparatus 300 includes a polishing table 320 and a top ring 330. The polishing table 320 is rotationally driven by a driving source, not shown. A polishing pad 310 is attached to the polishing table 320. The top ring 330 holds and presses a substrate against the polishing pad 310. The top ring 330 is rotationally driven by a driving source, not shown. The substrate is polished while being held and pressed against the polishing pad 310 by the top ring 330.

The substrate polishing apparatus 300 includes a processing solution supply nozzle 340 for supplying a processing solution or a dressing liquid to the polishing pad 310. The processing solution is, for example, a slurry containing abrasive particles. The dressing liquid is, for example, pure water. According to one embodiment, the processing solution supply nozzle 340 may be movable in a direction parallel to a surface of the polishing pad 310. This allows the processing solution supply nozzle 340 to supply the processing solution to any spot on the polishing pad 310 during the polishing of the substrate. For example, the processing solution supply nozzle 340 can be moved in synchronization with movement of the top ring 330 holding a substrate WF during the polishing of the substrate WF.

The substrate polishing apparatus 300 includes a dresser 350 for conditioning the polishing pad 310. The substrate polishing apparatus 300 includes an atomizer 360 for spraying liquid or a mixed fluid of liquid and gas toward the polishing pad 310. The liquid is, for example, pure water. The gas is, for example, a nitrogen gas. The dresser 350 and the atomizer 360 each may have any structure. The atomizer 360 does not necessarily have to be provided.

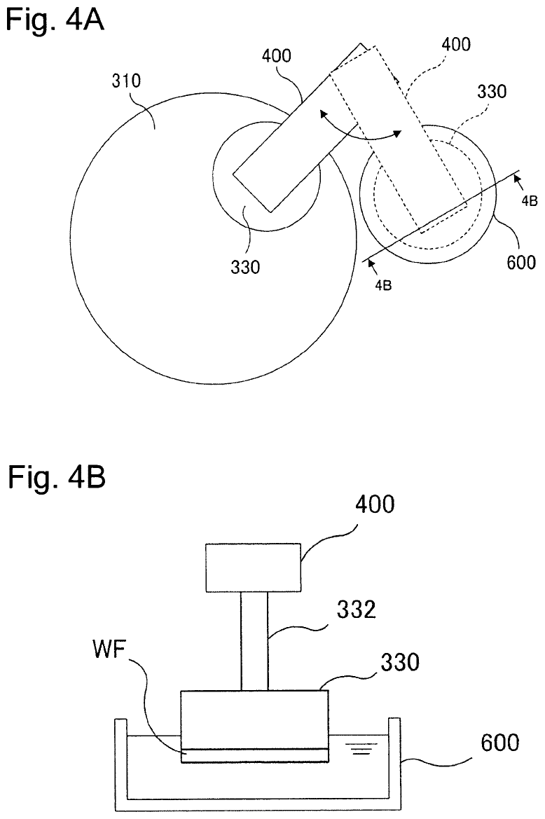

The top ring 330 is supported by a top ring shaft 332. The top ring 330 is rotatable around an axis of the top ring shaft 332 by a driving part, not shown, as shown by arrow AB. The top ring shaft 332 is capable of moving the top ring 330 in a direction perpendicular to the surface of the polishing pad 310 by a driving part, not shown. The top ring shaft 332 is connected to a pivotable arm 400 (see FIG. 4A). The pivotable arm 400 enables the top ring 330 to move in a direction parallel to the surface of the polishing pad 310 (in a radial direction, for example).

The polishing table 320 is supported by a table shaft 322. The polishing table 320 is rotated around an axis of the table shaft 322 as shown by arrow AC by a driving part, not shown. The polishing pad 310 is attached onto the polishing table 320. The polishing pad 310 may be any pad which is selected in consideration of a material of the substrate WF to be polished and desired polishing conditions. According to one embodiment, the polishing table 320 may include a cooling device for cooling the polishing pad 310. The polishing pad 310 can be adjusted in rigidity by adjusting temperature of the polishing pad 310. For example, if the polishing pad 310 is cooled and thus increased in rigidity, the polishing pad 310 has higher selectivity with respect to irregularities in the surface of the substrate WF to be polished. The cooling device may be, for example, a Peltier device provided to the polishing table 320 or may be a fluid passage formed in the polishing table 320 so that the cooling fluid controlled in temperature passes through the fluid passage. The cooling device of the polishing pad 310 may be formed of a pad contact member that contacts the surface of the polishing pad 310 and a liquid supply system that supplies liquid adjusted in temperature into the pad contact member. The liquid may be hot and cold waters, and a supply amount of each of the hot and cold waters supplied to the pad contact member may be controlled so that the pad contact member, and therefore the polishing pad 310, has predetermined temperature. The temperature control of the polishing pad 310 by the foregoing methods can be achieved in the following manner. For example, a temperature measuring instrument, such as a radiation thermometer, is provided separately to the substrate polishing apparatus 300, and a temperature signal obtained by measurement of the temperature measuring instrument is feedbacked to the cooling device. The surface of the polishing pad 310 thus attains the predetermined temperature.

The substrate WF is held by vacuum adsorption on a surface of the top ring 330, which faces the polishing pad 310. During polishing, the processing solution is supplied from the processing solution supply nozzle 340 to a polishing face of the polishing pad 310. During polishing, moreover, the polishing table 320 and the top ring 330 are rotationally driven. The substrate WF is polished by being pressed against the polishing face of the polishing pad 310 by the top ring 330.

According to one embodiment, the substrate polishing apparatus 300 may include an end point detecting system for sensing a polishing end point of the substrate WF. The end point detecting system may be any system, including publicly-known end point detecting systems. An Eddy current sensor, an optical sensor, a fiber sensor or the like may be provided to, for example, the polishing table 320 or the top ring 330. It is also possible, as the end point detecting system, to measure a change of torque in a drive device of the substrate polishing apparatus 300 to detect the polishing end point. During the polishing of the substrate WF using the polishing pad 310, when a layer to be polished of the substrate WF is finished, and a under layer is exposed, sliding resistance between the polishing pad 310 and the surface of the substrate WF is changed. The polishing end point of the substrate WF can be detected by detecting the change as a change of torque. The polishing end point can be detected, for example, by measuring change of in oscillation torque of the pivotable arm 400 or change of rotary torque of the top ring shaft 332.

According to one embodiment, the substrate polishing apparatus 300 includes a control unit 900. Operation of the substrate polishing apparatus 300 is controlled by the control unit 900. The control unit 900 may comprise an ordinary general-purpose computer, a dedicated-purpose computer, and the like, which include hardware devices, such as a storage unit, an input/output unit, a memory, a CPU, etc. The control unit 900 may comprise one or more hardware device.

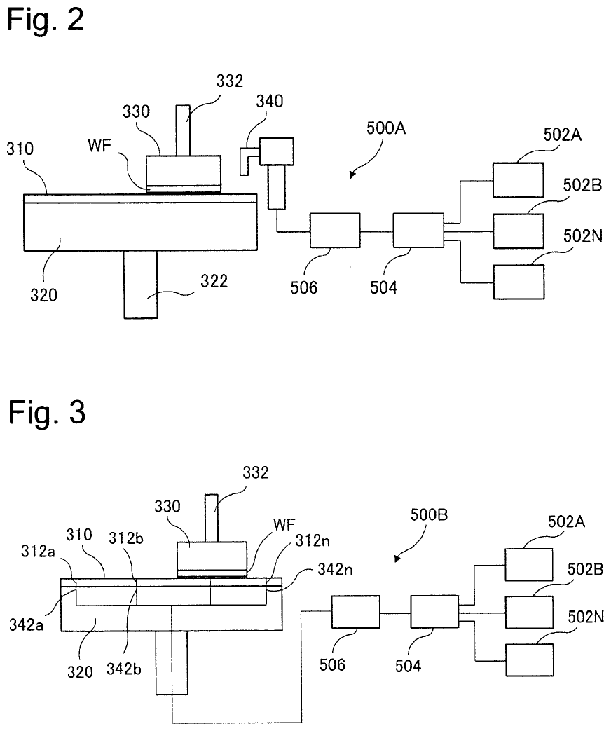

FIG. 2 is a lateral view schematically showing the substrate polishing apparatus 300 according to one embodiment. As illustrated in FIG. 2, the processing solution supply nozzle 340 is connected to a processing solution supply line 500A. As illustrated in FIG. 2, the processing solution supply line 500A includes a plurality of liquid sources 502 (a first liquid source 502A to an N-th liquid source 502N). The liquid sources 502 may be configured to hold a processing solution, pure water, a variety of conditioning agents, and the like, which are processing solutions. There is no limitation in the number of the liquid sources 502. The plurality of liquid sources 502 are connected to a mixer 504 via various valves, not shown. The mixer 504 is capable of mixing the liquid supplied from the plurality of liquid sources 502. For example, the first liquid source 502A is made to hold a processing solution with a reference concentration, and the second liquid source 502B is made to hold pure water. The processing solution can be diluted to desired concentration by mixing the processing solution supplied from the first liquid source with the pure water supplied from the second liquid source 502B. The liquid sources 502 may be configured to hold liquid for conditioning the processing solution, such as processing solutions different in abrasive particle concentration, a pH conditioning agent, an oxidizing agent, a reductant, an acid component, an alkaline component, an electrolyte solution, a complexation agent, and a surface-active agent, thus conditioning the processing solution containing desired components using the mixer 504. According to one embodiment, the mixer 504 may include a temperature gauge and a temperature adjusting device. If the mixer 504 includes the temperature gauge and the temperature adjusting device, the processing solution at desired temperature can be supplied from the processing solution supply nozzle 340 onto the polishing pad 310. The temperature gauge and the temperature adjusting device may be provided separately from the mixer 504.

According to one embodiment, the processing solution supply line 500A includes a sensor 506 located downstream of the mixer 504 as illustrated in FIG. 2. The sensor 506 is intended to detect the concentration of each component contained in the processing solution that is conditioned by the mixer 504. For example, the sensor 506 may be a pH meter, an oxidation-reduction potentiometer, a particle sensor that measures abrasive particle concentration in a processing solution, or another like sensor. According to one embodiment, the sensor 506 may be provided to the mixer 504. If the mixer 504 is provided with the sensor 506, a supply amount of liquids supplied from the liquid sources 502 can be adjusted so as to obtain the processing solution with the desired concentration within the mixer 504.

FIG. 3 is a lateral view schematically showing the substrate polishing apparatus 300 according to one embodiment. In the embodiment illustrated in FIG. 3, the substrate polishing apparatus 300 includes a processing solution supply line 500B. In the embodiment illustrated in FIG. 3, the processing solution supply line 500B is similar to the embodiment illustrated in FIG. 2 in that the processing solution supply line 500B includes the plurality of liquid sources 502, the mixer 504, and the sensor 506. The embodiment illustrated in FIG. 3, however, is so configured that the processing solution is supplied onto the surface of the polishing pad 310 through a conduit formed through the table shaft 322 and the polishing table 320. More specifically, the conduit extends from the sensor 506 to the table shaft 322 and the polishing table 320. The conduit diverges inside the polishing table 320. Outlets 342a, 342b to 342n are defined by diverged conduits in the surface of the polishing table 320. There is no limitation in the position and number of the outlets 342a to 342n. Solenoid valves or the like, not shown, are placed in the diverged conduits. The substrate polishing apparatus 300 is thus capable of supplying the processing solution from a freely-selected one or more of the outlets 342a to 342n. Through-holes 312a to 312n are formed in the polishing pad 310 in positions coinciding with the outlets 342a to 342n. This allows the processing solution to be supplied onto the surface of the polishing pad 310 through the outlets 342a to 342n of the polishing table 320 and the through-holes 312a to 312n of the polishing pad 310. During the polishing of the substrate WF, for example, the processing solution is supplied from the outlets 342a to 342n and the through-holes 312a to 312n which are located where the substrate WF is located. By so doing, the processing solution can be efficiently supplied to a contact face between the substrate WF and the polishing pad 310. According to one embodiment, the substrate polishing apparatus 300 may include both the processing solution supply line 500A illustrated in FIG. 2 and the processing solution supply line 500B illustrated in FIG. 3. In this case, the processing solution supplied through the processing solution supply line 500A and the processing solution supplied through the processing solution supply line 500B may differ in kind and predetermined component concentration. FIGS. 2 and 3, for the sake of clarity of illustrations, omit constitutions other than the polishing table 320, the top ring 330, the processing solution supply nozzle 340, and the processing solution supply lines 500A and 500B. It is possible to add, for example, constitutions such as the dresser 350 and the atomizer 360 shown in FIG. 1 or any other freely-selected constitutions.

FIG. 4A is a top view schematically showing the substrate polishing apparatus 300 according to one embodiment. The substrate polishing apparatus 300 illustrated in the figure includes the polishing table 320 attached with the polishing pad 310, the top ring 330 that holds the substrate WF, and the arm 400 for rotating the top ring 330, as with the substrate polishing apparatus 300 illustrated in FIG. 1. The substrate polishing apparatus 300 illustrated in FIG. 4A further includes a reaction solution bath 600 for containing a reaction solution. FIG. 4B is a lateral view of the top ring 330 that holds the reaction solution bath 600 and the substrate WF, as viewed from direction of arrow 4B shown in FIG. 4A. Although the substrate polishing apparatus 300 illustrated in FIG. 4 includes a single reaction solution bath 600, the substrate polishing apparatus 300 may be configured to include a plurality of reaction solution bath 600 as discussed later. As illustrated in FIG. 4B, the reaction solution bath 600 contains a reaction solution. The reaction solution bath 600 has a temperature controlling function and is configured to maintain the reaction solution at predetermined temperature. As illustrated in FIG. 4A, the arm 400 is capable of rotating the top ring 330 to retreat the substrate WF from the polishing pad 310, transferring the substrate WF to a position of the reaction solution bath 600 (shown by broken lines in FIG. 4A), and bringing the substrate WF into contact with the reaction solution (FIG. 4B). The reaction solution may be liquid containing an oxidizing agent, a complexation agent, and the like, for forming a brittle reaction layer on a surface of a surface to be polished of the substrate WF. For example, if the surface to be polished of the substrate WF includes an oxide film, the reaction solution may contain an alkaline agent, such as potassium hydroxide (KOH). If the surface to be polished of the substrate WF includes tungsten, the reaction solution may contain the oxidizing agent, such as potassium iodate and hydrogen peroxide. If the surface to be polished of the substrate WF includes copper, the reaction solution may contain an oxidizing agent, such as hydrogen peroxide and ammonium persulfate, and a complexation agent, such as benzotriazole (BTA) and various kinds of chelate agents (including quinaldic acid), which is intended to form an insoluble complex on a surface. In the planarization process in a common semiconductor-device fabricating process, the aforementioned multiple materials that are objects of removal are intermixed. Planarization is accomplished by polishing the multiple materials at the same time. For that reason, the aforementioned reaction solution components may be contained in one reaction solution. If the reaction solution components are deteriorated by being contained together in one solution, the reaction solution bath 600 may comprise a plurality of reaction solution baths 600 so that the reaction solution components may be contained in the respective reaction solution baths 600. In this case, reaction layers are formed by bringing the substrate WF into contact with the respective reaction solution baths 600. If the substrate WF is planarized in a state where the plural materials mentioned above are on the surface to be polished of the substrate WF, it is necessary in some cases to differentiate rate of removing the materials. In such a case, it is possible to differentiate formation amounts of the reaction layers (thickness of the reaction layers) with respect to the materials and differentiate removal amounts of the reaction layers in a polishing removal process discussed later. The formation amounts of the reaction layers may be differentiated by controlling concentrations of the components or by adding an inhibitor that suppresses a formation reaction of the reaction layers. The inhibitor is, for example, of a type that is adsorbed to a to-be-removed material, such as a surface-active agent, to suppress the formation of a reaction layer or of a type that neutralizes or counters the reaction component itself, for example, like a reductant acting on an oxidizing agent. In many cases, a reaction layer is formed basically by a chemical reaction. Therefore, the formation amounts of the reaction layers on the materials may be differentiated, for example, by controlling temperature of the reaction solution. If the substrate polishing apparatus 300 is configured to include the plurality of reaction solution baths 600, the formation amounts of the reaction layers may be differentiated by differentiating solution temperatures of the reaction solution baths 600. Furthermore, when the plurality of reaction solution baths 600 are arranged, the formation amounts of the reaction layers can be differentiated by controlling a duration of contact of the substrate WF with the reaction solution within the reaction solution baths 600. In the planarization process carried out in the common conductor-device fabricating process, the to-be-removed materials themselves often have roughness generated in the process of producing the to-be-removed materials. It is then also necessary to remove the roughness when the planarization is carried out. When the planarization takes place, if a protective layer discussed later is formed before or after the formation of the reaction layers, the efficiency of the planarization is increased. The protective layer can be formed on the substrate WF, for example, by further providing another solution bath containing a chemical for forming the protective layer and properly transferring the top ring 330 between the reaction solution baths 600 and the solution bath for forming the protective layer in the substrate polishing apparatus 300. After the brittle reaction layer is formed on the surface of the substrate WF in the foregoing manner, the substrate WF is pressed against the polishing pad 310 and thus polished so as to remove the brittle reaction layer. The process of bringing the substrate WF into contact with the reaction solution and the process of polishing and removing the reaction layer formed on the surface of the substrate WF are repeatedly carried out. Desired polishing is thus accomplished.

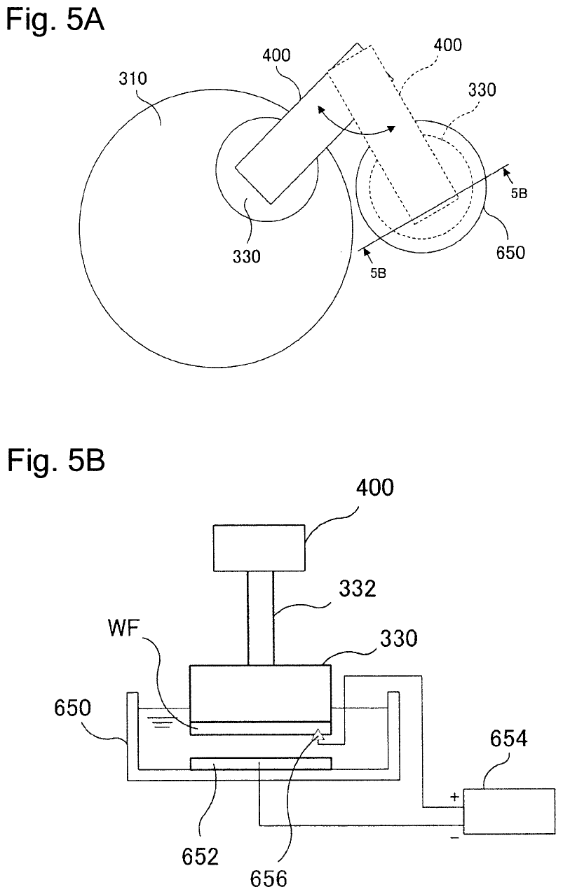

FIG. 5A is a top view schematically showing the substrate polishing apparatus 300 according to one embodiment. The substrate polishing apparatus 300 illustrated in the figure includes the polishing table 320 attached with the polishing pad 310, the top ring 330 that holds the substrate WF, and the arm 400 for rotating the top ring 330, as with the substrate polishing apparatus 300 illustrated in FIG. 1. The substrate polishing apparatus 300 illustrated in FIG. 5A further includes an electrolyte solution bath 650 for holding an electrolyte solution. FIG. 5B is a lateral view of the top ring 330 that holds the electrolyte solution bath 650 and the substrate WF, as viewed from direction of arrow 5B shown in FIG. 5A. The electrolyte solution bath 650 contains the electrolyte solution. The electrolyte solution bath 650 has a temperature controlling function and is configured to maintain the electrolyte solution at predetermined temperature. As illustrated in FIG. 5A, the arm 400 is capable of rotating the top ring 330, retreating the substrate WF form the polishing pad 310, transferring the substrate WF to a position of the electrolyte solution bath 650 (shown by broken lines in FIG. 5A), and bringing the substrate WF into contact with the electrolyte solution (FIG. 5B). The electrolyte solution may be liquid containing an electrolyte for providing an electric action to the surface of the surface to be polished of the substrate WF and a complexing agent or the like. For example, if the surface to be polished of the substrate WF contains copper, the electrolyte solution contains, for example, inorganic neutral salt, such as potassium sulfate, or organic salt, as the electrolyte, and also contains various kinds of inorganic acids and inorganic alkalis, and inorganic acid salts and alkali salts, as the pH conditioning agent. An example of the alkali salts is KOH. The electrolyte solution may contain, for example, BTA or chelate agents (including quinaldic acid) as the complexing agent. In addition, if the reaction layer is formed by an electrolytic reaction, there is a possibility that electrolyte etching occurs as a side reaction, so that an etching inhibitor for preventing the electrolyte etching may be introduced. Inhibitors include a so-called corrosion inhibitor. For example, if a nitrogen-containing heterocyclic compound is introduced, the heterocyclic compound may be one that is known as a chemical compound that forms a chemical compound with metal, such as copper to be processed, and forms a protective layer on a metal surface to suppress metal corrosion.

As illustrated in FIG. 5B, an opposite electrode 652 is disposed in a bottom portion of the electrolyte solution bath 650. The opposite electrode 652 is connected to a minus terminal of an electric power source 654. The substrate polishing apparatus 300 according to the embodiment illustrated in FIG. 5B includes a feed pin 656 connected to a plus terminal of the electric power source 654. The feed pin 656 can be connected to a conductive layer (metal layer) on the surface of the substrate WF. It is then possible to provide electric current to the conductive layer on the surface of the substrate WF through the electrolyte solution contained in the electrolyte solution bath 650 and thus form on the surface of the conductive layer, a brittle reaction layer or an oxide layer formed by electrolytic oxidation. The oxide layer may be formed eventually as a reaction layer by introducing a complexation agent into the electrolyte solution. The reaction layer that is formed can be controlled by controlling a quantity of electric charge provided to the conductive layer of the substrate WF. According to one embodiment, the quantity of electric charge can be controlled by measuring the quantity of electric charge provided to the conductive layer of the substrate WF using a coulomb meter. After the reaction layer comprising the brittle oxide layer and a complex is formed on the surface of the substrate WF, the substrate WF is pressed against the polishing pad 310 to polish the substrate WF so as to remove the brittle reaction layer. The desired polishing can be accomplished by repeatedly carrying out the process of bringing the substrate WF into contact with the electrolyte layer and providing the electric current to the surface of the substrate WF and the process of polishing and removing the reaction layer formed on the surface of the substrate WF.

An embodiment of a polishing method according to the invention will be discussed below. According to one embodiment, the substrate WF is subjected to chemical mechanical polishing (CMP). For example, the CMP is generally carried out to planarize the substrate WF in the process of fabricating semiconductor devices. There has been more and more demand for planarization in the semiconductor-device fabricating process. For example, planarization in the order of several nanometers is desired. The polishing method discussed below can be carried out using the foregoing substrate polishing apparatus 300.

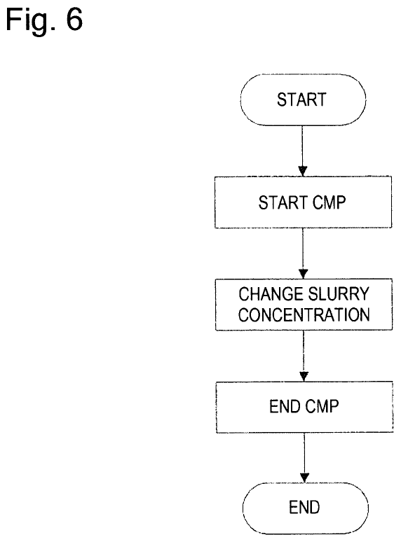

FIG. 6 is a schematic flowchart showing the polishing method according to one embodiment. The polishing method according to one embodiment performs the polishing of the substrate WF on polishing conditions of the common CMP that has been conventionally carried out. The polishing conditions include, for example, kinds and concentrations of processing solutions used for the polishing, rotational rate of the substrate WF and of the polishing pad 310, a pressing force of the substrate WF and the polishing pad 310, a polishing duration, etc. According to common CMP polishing, the polishing conditions are selected so as to achieve rapid polishing and yet ensure planarity of the substrate WF by the polishing. According to one embodiment, when the substrate WF is polished close to a polishing goal by performing the CMP on the general polishing conditions, the polishing conditions are changed for more accurate planarization of the substrate WF. More specifically, an effective component in the processing solution, which contributes to the polishing of the substrate WF, can be decreased in concentration. The effective component contained in the processing solution may be (1) a component that oxidizes the layer to be polished of the substrate, (2) a component that dissolves the layer to be polished of the substrate, (3) a component that exfoliates the layer to be polished of the substrate, or another like component. The concentration of the effective component in the processing solution can be changed by configuration of the processing solution supply line 500A and the processing solution supply line 500B. The concentration of the processing solution can be changed, for example, by configuring the processing solution supply lines 500A and 500B so that the plurality of liquid sources 502 contain a reference processing solution, pure water, and liquid for conditioning various kinds of components, and that components of desired amounts are mixed together by the mixer 504. As an example, every kind of component contained in the processing solution can be diluted by mixing the reference processing solution and the pure water. For example, when the layer to be polished of the substrate WF includes an oxide film, SiO₂ of the oxide film is turned into silanol and made brittle by increasing pH. Therefore, an alkaline agent may be reduced in concentration. When the layer to be polished of the substrate WF includes metals, such as copper and tungsten, these metals are oxidized and then complexed to become brittle. Therefore, an oxidizing agent may be reduced in concentration. In all the foregoing cases, the brittle layer formed on the surface of the substrate WF is eventually removed by action such as adsorption using abrasive particles, such as colloidal silica. Therefore, the abrasive particles may be reduced in concentration.

According to the polishing method of one embodiment, the thickness of the layer to be polished of the substrate is measured. The measurement of thickness of the layer to be polished of the substrate makes it possible, for example, to detect a state in which the substrate is polished close to the polishing goal by the common CMP, and also detect that the substrate is polished to a final polishing goal. According to one embodiment, the effective component in the processing solution may be changed in concentration step by step while measuring the thickness of the layer to be polished of the substrate. The thickness of the layer to be polished of the substrate can be measured using various kinds of an end point detecting system, such as the foregoing Eddy current sensor.

According to the polishing method of one embodiment, the pH of the processing solution is measured during the polishing of the substrate. During the CMP, the pH of the processing solution effects polishing rate. The polishing rate therefore can be adjusted by changing the effective component in the processing solution according to the measured pH while the pH of the processing solution is monitored. When hydrogen peroxide is used as the oxidizing agent, for example, an oxidation reaction progresses faster on an alkaline side. Therefore, the action of the oxidizing agent can be adjusted by changing the pH. If the pH of the processing solution is monitored, the effect of each component that contributes to a polishing reaction can be adjusted.

According to the polishing method of one embodiment, during the substrate polishing, the processing solution contains abrasive particles, and the abrasive particles contained in the processing solution are measured in concentration. During the CMP, the abrasive particle concentration in the processing solution effects the polishing rate. The polishing rate therefore can be adjusted by changing the effective component in the processing solution according to the measured abrasive particle concentration while the abrasive particle concentration in the processing solution is monitored. For example, if the reaction layer to be polished is thinly formed to achieve the polishing on an atomic layer level, if a more than necessary amount of abrasive particles exist in a polishing space, there is a possibility that the substrate surface has a cut or a scratch. To avoid the scratch, the monitoring of the abrasive particle concentration is effective.

According to the polishing method of one embodiment, the processing solution contains an oxidizing component that oxidizes the layer to be polished of the substrate. Addition of a reductant for suppressing an oxidation action in the processing solution makes it possible to change the concentration of the oxidizing component contained in the processing solution in an effective manner. For example, in the case of polishing in a damascene process for producing copper interconnects, a barrier layer is subjected to polishing removal after the polishing removal of a copper layer. If planarization in an atomic layer order is subsequently performed, polishing can be carried out using the processing solution, from which oxidizing agent is removed, after being used for the polishing of the barrier layer which corresponds to a preceding process. However, the copper is oxidized to a certain degree by a remaining oxidizing agent, such as hydrogen peroxide, and also by dissolved oxygen in the processing solution. The oxidation reaction can be therefore controlled by adding a reductant, such as sulfite, while a potential is monitored by an oxidation-reduction potentiometer.

According to the polishing method of one embodiment, the processing solution contains acid as a soluble component. The soluble component contained in the processing solution can be changed in concentration by adding an alkaline agent into the processing solution. For example, if the layer to be polished of the substrate WF includes tungsten, potassium iodate having a high oxidizing power is sometimes used as an oxidizing agent to achieve a sufficient polishing rate. Iodic acid exerts a high oxidizing power when pH is low. When planarization in the atomic layer order is performed, therefore, the alkaline agent, such as KOH, is added into the processing solution used in the common CMP to increase the pH, thereby reducing the polishing rate to the desired polishing rate.

According to the polishing method of one embodiment, the processing solution contains alkali as a soluble component. The soluble component contained in the processing solution can be changed in concentration by adding acid into the processing solution. For example, when the layer to be polished of the substrate WF includes an oxide film, SiO₂ of the oxide film is turned into silanol and made brittle by increasing pH. The polishing rate therefore can be reduced by decreasing the concentration of the alkaline agent.

According to the polishing method of one embodiment, the temperature of the processing solution is changed during the polishing of the substrate. The temperature of the processing solution effects the polishing rate of the CMP. The polishing rate therefore can be adjusted by changing the temperature of the processing solution during the polishing of the substrate. According to the polishing method of one embodiment, the temperature change of the processing solution can be made according to the thickness of the layer to be polished of the substrate.

The polishing method of the above-discussed embodiment is a method carried out when a single substrate is polished, but is also adoptable when a plurality of substrates are serially polished. For example, it is possible to use a first processing solution to polish a first substrate, and use a second processing solution to polish a second substrate. The first processing solution and the second processing solution may have different concentrations of effective components. The concentration of the effective component can be changed according to a result of polishing of each substrate. For example, thickness and planarity of the layer on the surface of the polished substrate are inspected. Based on results of the inspection, the component concentration in the processing solution used when the substrate is polished, and other like factors, the processing solution to be used for the subsequent substrate polishing can be changed.

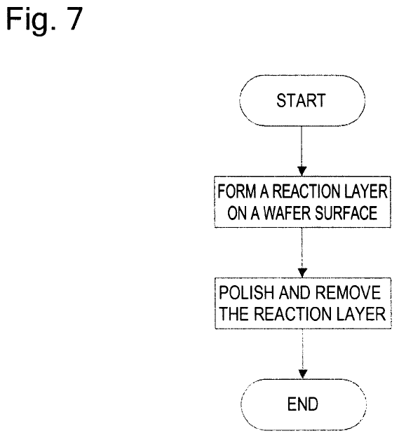

According to the polishing method of one embodiment, the metal layer formed on the surface of the substrate can be removed. FIG. 7 is a schematic flowchart showing a method of removing the metal layer that is formed on the surface of the substrate according to one embodiment. According to the method of one embodiment, an oxidizing agent and/or a complexation agent is intermittently supplied to the metal layer of the surface of the substrate, to thereby form a brittle reaction layer on the surface of the metal layer. The oxidizing agent and/or the complexation agent can be supplied from the processing solution supply nozzle 340 through the processing solution supply line 500A to the polishing pad 310 and the surface of the substrate WF. The oxidizing agent and/or the complexation agent also may be supplied from under the polishing pad 310 toward the substrate WF through the processing solution supply line 500B. It is also possible to use both the processing solution supply line 500A and the processing solution supply line 500B. According to one embodiment, the oxidizing agent and/or the complexation agent may be contained in the reaction solution bath 600 discussed with reference to FIGS. 4A and 4B, and the substrate WF may be brought into contact with the reaction solution contained in the reaction solution bath 600 to form the brittle reaction layer on the surface of the metal layer as illustrated in FIG. 4B. A supply amount of the oxidizing agent and/or the complexation agent may be changed during the processing of the substrate. For example, the supply of the oxidizing agent may be increased by stages while the substrate is processed. In order to achieve the polishing removal in the order of several nanometers, it is desired that the reaction layer be quite thin and have a thickness of the atomic layer order. To that end, the oxidizing agent and/or the complexation agent for forming the reaction layer is very dilute and is, for example, 10 μmol/L of chemical or the like. Considering that the chemical has to be prevented from permeating inside the substrate WF, it is desired that the oxidizing agent and the complexation agent are large in molecular weight. The reaction layer that is formed preferably has a high density. The surface of the substrate WF may be cleaned before the reaction layer is formed on the metal layer of the substrate WF. This cleaning is performed to remove a natural oxide film or an unintended film which is formed in some cases on the surface of the substrate WF. A reductant may be used to remove the natural oxide film formed on the surface of the substrate WF.

After the brittle reaction layer is formed on the metal layer on the surface of the substrate WF in the above-described manner, the polishing pad 310 is pressed against the reaction layer to polish and remove the reaction layer in the presence of the processing solution containing abrasive particles. At this time, the concentration of the effective component in the processing solution can be changed in the manner similar to the above-discussed embodiment. The process of forming the reaction layer on the surface of the substrate WF and the process of polishing and removing the reaction layer are repeatedly performed, thereby accomplishing the desired polishing. According to the present embodiment, the intermittent supply of the oxidizing agent and/or the complexation agent makes it possible to intermittently form the reaction layer and control the polishing rate with accuracy. It is ideal that the polishing removal remove only the reaction layer, so that the polishing removal does not have to be carried out at a similar polishing rate to the common CMP. It is desired that the polishing rate be, for example, 10 nm/min or less. Since planarization is also necessary, the polishing removal needs to control the contact between the polishing pad and the substrate WF more than the common CMP. Contact pressure of the polishing pad with respect to irregularities in the surface of the to-be-removed material of the substrate WF is preferably highly selective. For example, as a polishing condition, a smaller polishing pressure is more favorable. The polishing pressure is preferably 1 psi or less, or more preferably 0.1 psi or less. The surface of the polishing pad 310 may be increased in rigidity by being smoothed through adjustment of dressing conditions and the like or may be cooled using the cooling device of the polishing pad 310. A polishing pad with high rigidity as in bonded abrasive may be used.

According to the method of one embodiment, after the polishing removal of the reaction layer, the substrate can be polished by pressing the polishing pad 310 against the surface of the substrate WF in the presence of pure water only. The present embodiment prevents the abrasive particles contained in the processing solution from causing damage to the metal layer under the reaction layer after the brittle reaction layer on the substrate WF is removed by the polishing pad 310.

According to the method of one embodiment, the oxidizing agent and/or the complexation agent is supplied onto the polishing pad 310 in a state where the substrate WF and the polishing pad 310 are not in contact with each other. If the substrate WF and the polishing pad 310 are in contact with each other, there is a possibility that the oxidizing agent and/or the complexation agent is not evenly supplied onto the polishing pad 310, and therefore, onto the substrate WF. To solve this problem, the present embodiment previously supplies the oxidizing agent and/or the complexation agent onto the polishing pad 310 in the state where the substrate WF and the polishing pad 310 are not in contact with each other. The embodiment thus makes it possible to evenly supply the oxidizing agent and/or the complexation agent. More specifically, the oxidizing agent and/or the complexation agent can be supplied to the polishing pad 310 using the processing solution supply line 500A or the processing solution supply line 500B with the top ring 330 pulled up from the polishing pad 310. When the oxidizing agent and/or the complexation agent is supplied to the polishing pad 310, the polishing table 320 may be rotated. A centrifugal force generated by rotation of the polishing table 320 allows the oxidizing agent and/or the complexation agent to be uniformly distributed within the surface of the polishing pad 310 in a short time.

According to the method of one embodiment, one or some of the components of the processing solution for substrate polishing may be supplied from above the polishing pad 310, and one or some of the components of the processing solution may be supplied from under the polishing pad 310. To be specific, the components in the processing solution supplied through the processing solution supply line 500A may differ from the components in the processing solution supplied through the processing solution supply line 500B. For example, when the metal film on the surface of the substrate WF is polished, the oxidation of the metal controls the speed of the process. To polish the substrate in the atomic layer order, therefore, only a very small amount of oxidizing agent which is needed for the atomic layer order polishing is supplied. However, according to a processing solution supply method carried out by ordinary CMP apparatus, which supplies all the components of a processing solution from above the pad, a peripheral edge of the substrate WF is first to contact a fresh processing solution, so that only the peripheral edge is selectively oxidized if the amount of the oxidizing agent is small, and the metal film located in a center portion of the substrate WF is not polished. When the oxidation film is polished, the exfoliation of the brittle layer by the abrasive particles controls the rate of the polishing reaction. In this case, the polishing in the atomic layer order is achieved by reducing the amount of the abrasive particles. In this case, too, if the method of supplying all the processing solution components from above the pad is carried out, the peripheral edge of the substrate WF is first to contact the fresh processing solution, effective abrasive particles are worn out by polishing the peripheral edge, and the metal film in the center portion of the substrate WF is not polished. As an example, therefore, it is effective to supply the component that controls the rate of the polishing reaction from under the polishing pad 310 and supply other components from above the polishing pad 310 as in the conventional art.

In the method of removing the metal layer formed on the surface of the substrate WF according to one embodiment, the electrolyte solution is supplied to the metal layer of the substrate. Electric current is then supplied to the metal layer of the substrate WF through the electrolyte solution, which makes it possible to form on the metal layer surface the brittle reaction layer, and also the oxide layer by electrolytic oxidation. The oxide layer may be formed eventually as the reaction layer by introducing the complexation agent into the electrolyte solution. At this time, the thickness of the reaction layer that is formed can be controlled by magnitude and supply duration of the electric current. The reaction layer that is formed can be controlled by controlling the quantity of the electric charge provided to the conductive layer of the substrate WF. As one embodiment, the quantity of the electric charge can be controlled by measuring the quantity of the electric charge provided to the conductive layer of the substrate WF using the coulomb meter. The magnitude and supply duration of the electric current supplied to the substrate may be changed in order to achieve the desired thickness of the reaction layer. The method of the present embodiment can be carried out, for example, by the configuration discussed above with reference to FIGS. 5A and 5B. According to the present embodiment, after the reaction layer is formed in the metal layer by an electrical action, the polishing pad 310 is pressed against the surface of the substrate WF to polish and remove the reaction layer. In this polishing removal, it is ideal to remove only the reaction layer. The polishing rate as in the common CMP is therefore not necessary. It is desired that the polishing rate be, for example, 10 nm/min or less. Since planarization also has to be performed, the contact between the polishing pad and the substrate WF needs to be controlled more in the polishing removal than in the common CMP. Contact pressure of the polishing pad with respect to irregularities in the surface of the to-be-removed material of the substrate WF is preferably highly selective. For example, as a polishing condition, a smaller polishing pressure is more favorable. The polishing pressure is preferably 1 psi or less, or more preferably 0.1 psi or less. It is also possible to use a method of increasing the rigidity of the surface of the polishing pad 310 by smoothing the polishing pad surface through adjustment of dressing conditions and the like or by cooling the polishing pad surface using the cooling device of the polishing pad 310. A polishing pad with high rigidity as in bonded abrasive may be used. Furthermore, the processing solution may be one in which effective components, such as the abrasive particles, are properly conditioned. If the reaction layer is sufficiently brittle, the reaction layer can be polished and removed with the polishing pad 310 pressed against the surface of the substrate WF in the presence of pure water only. This prevents the damage caused to the metal layer under the reaction layer.

According to the method of one embodiment, there is provided a method of removing a silicon oxidation layer formed on a substrate. The method supplies an adsorptive surface-active agent to the silicon oxidation layer to form a protective layer on a surface of the silicon oxidation layer. According to one embodiment, the adsorptive surface-active agent can be supplied using the processing solution supply line 500A and/or the processing solution supply line 500B. According to the method of the present embodiment, after the protective layer is formed, the polishing pad 310 is pressed against the protective layer formed on the substrate WF in the presence of the processing solution to polish the protective layer. The silicon oxidation layer is thus polished and removed. In this process, the pad can be supplied with an additive that accelerates the adsorption of abrasive particles to the polishing pad 310. It is known that, for example, addition of picoline acid to the processing solution increases an amount of adsorption of ceria (cerium oxide), or abrasive particles, to the polishing pad 310 per unit area. The substrate polishing rate thus can be controlled by adding an additive like the one mentioned above into the processing solution.

According to each of the above-discussed embodiments of the substrate polishing method, the kind of the processing solution, the concentration and supply amount of the components, the pressing force and contact duration between the substrate WF and the polishing pad 310, the rotational rate of the top ring 330 and the polishing table 320, etc. can be changed. These processing conditions may be changed during the processing of one substrate. Alternatively, the processing conditions may be changed with respect to each substrate to be processed when a plurality of substrates are processed. The substrate to be polished can be freely selected. The metal layer to be polished may contain, for example, at least any one of aluminum, tungsten, copper, ruthenium, cobalt, titanium, tantalum, and an alloy or chemical compound of the foregoing metals. An insulation layer to be polished may include at least one of an oxide silicon layer, a silicon nitride layer, a low-k layer, and a high-k layer.

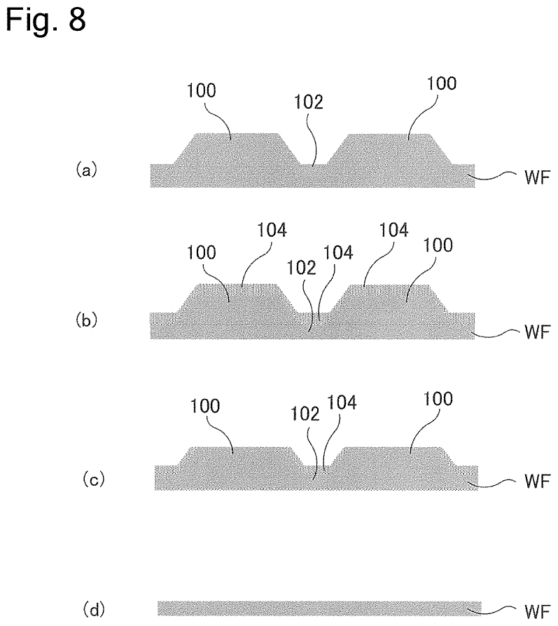

The following description explains an example of substrate polishing by the substrate polishing methods of the above-discussed embodiments. FIG. 8 show an example of substrate planarization by polishing according to one embodiment. FIG. 8(a) shows an initial state of a to-be-removed layer that is formed on a substrate surface from a lateral view. The to-be-removed layer may be an insulation layer, such as an oxide silicon layer, a silicon nitride layer, a low-k layer, and a high-k layer, or may contain at least one of aluminum, tungsten, copper, ruthenium, cobalt, titanium, tantalum, and an alloy or chemical compound of the foregoing metals. According to the present example, the to-be-removed layer of the substrate WF includes convex portions 100 and concave portion 102. As one example, the convex portions 100 are of a nanometer-level size. FIG. 8 show a method of removing the convex portions 100 of the to-be-removed layer and thus obtaining a planarized substrate illustrated in FIG. 8(d). In the example illustrated in FIG. 8, a brittle reaction layer 104 is formed on the surface of the substrate (FIG. 8(b)). The reaction layer is formed both in the convex portions 100 and the concave portions 102 of the substrate WF. The reaction layer 104 is preferably formed with a thickness of an atomic layer unit on a several A level. The reaction layer 104 can be formed using any of the foregoing apparatuses and methods. The reaction layer 104 formed on the convex portions 100 is then removed by removal technique with a step height selectivity (FIG. 8(c)). For example, the reaction layer 104 can be removed by the substrate polishing apparatus 300 or a Catalyst-Referred Etching(CARE) method. The formation and removal of the reaction layer 104 are repeatedly performed, to thereby remove the convex portions 100 of the substrate WF and obtain the planarized substrate WF (FIG. 8(d)). When the to-be-removed layer is the oxide layer, the reaction layer 104 is a brittle layer formed, for example, by increasing pH to turn SiO₂ of the substrate WF into silanol. When the to-be-removed layer is a metal layer made of tungsten, copper or another like metal, the reaction layer 104 is a metal oxide or complex layer made of the oxidizing agent and/or the complexation agent. In the polishing removal of the reaction layer 104 by the substrate polishing apparatus 300, it is ideal to remove only the reaction layer 104 on the convex portions 100. The polishing rate as in the common CMP is therefore not needed. The polishing rate is desirably, for example, 10 nm/min or less. Since planarization also has to be performed, the contact between the polishing pad 310 and the substrate WF needs to be controlled more than in the common CMP. Therefore, the contact pressure of the polishing pad 310 with respect to irregularities in the surface of the to-be-removed material of the substrate WF is preferably highly selective. For example, as a polishing condition, a smaller polishing pressure is more favorable. The polishing pressure is preferably 1 psi or less, or more preferably 0.1 psi or less. It is also possible to increase the rigidity of the surface of the polishing pad 310 by smoothing the surface of the polishing pad 310 through adjustment of dressing conditions and the like or by cooling the surface of the polishing pad 310. In order to prevent the abrasive particles in the processing solution from causing damage to a under layer (unreacted layer) of the reaction layer 104 after the removal of the brittle reaction layer 104 on the substrate WF, it is preferable, to reduce the removal unit, that the polishing processing solution contain, for example, abrasive particle components only, and that an abrasive particle size be smaller than an abrasive particle size in the common CMP, or more specifically, as small as 20 nm or less. Abrasive particle concentration may also be reduced without decreasing the uniformity of polishing amount within the surface of the substrate WF. The pH is also associated with adsorption of the abrasive particles to the surface and clumping of the abrasive particles themselves, so that the pH may be properly conditioned using a pH conditioning agent. The foregoing description explains the example of polishing removal of the reaction layer 104 using the abrasive particles. If the reaction layer 104 is sufficiently brittle, the substrate may be polished by pressing the polishing pad 310 against the surface of the substrate WF in the presence of pure water only.

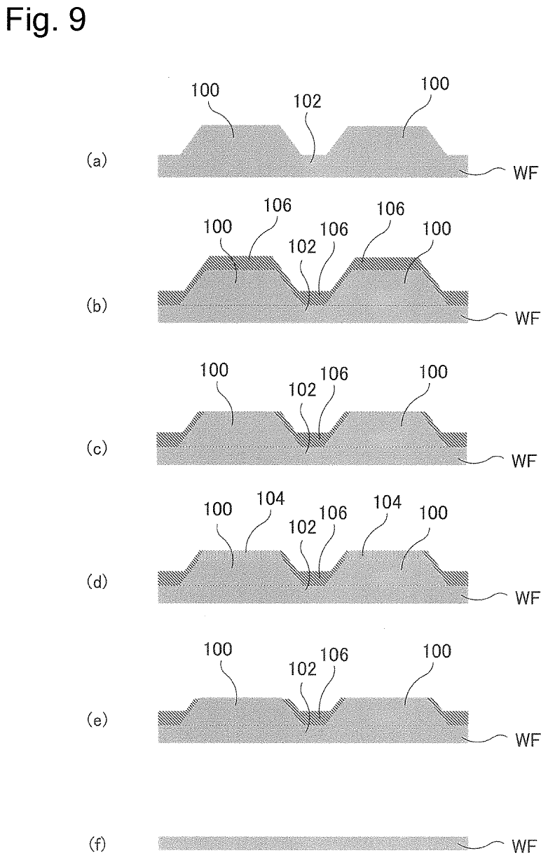

FIG. 9 show an example of substrate planarization by polishing according to one embodiment. Like the example illustrated in FIG. 8, the example illustrated in FIG. 9 also shows the planarization of the substrate including the convex portions 100 and the concave portions 102. FIG. 9(a) shows an initial state of a to-be-removed layer that is formed on a substrate surface from a lateral view. As an example, the convex portions 100 are of a nanometer-level size. In the example illustrated in FIG. 9, a protective layer 106 is first formed on the entire surface of the substrate WF (FIG. 9(b)). It is desirable that the polishing rate has lower dependence on the polishing pressure in the polishing of the protective layer 106, as compared to in the polishing of the reaction layer 104. After the formation of the protective layer 106, the protective layer 106 on the convex portions 100 is polished and removed (FIG. 9(c)). The protective layer 106 can be polished and removed, for example, using the substrate polishing apparatus 300 and the polishing method described above. After the removal of the protective layer 106 on the convex portions 100, the reaction layer 104 is formed (FIG. 9(d)). At this time, the convex portions 100 are exposed, whereas the concave portions 102 are covered with the protective layer 106. The reaction layer 104 is therefore formed on each of the convex portions 100. The reaction layer 104 is preferably formed with a thickness of an atomic layer unit on a several A level. The reaction layer 104 can be formed using any of the foregoing apparatuses and methods. After the formation of the reaction layer 104, only the reaction layer 104 is removed (FIG. 9(e)). The reaction layer 104 can be removed by the substrate polishing apparatus 300 or the Catalyst Referred Etching (CARE) method. If the protective layer 106 has an etching resistance, the reaction layer 104 may be removed by etching. The formation and removal of the reaction layer 104 are repeatedly performed, to thereby remove the convex portions 100 of the substrate WF and obtain the planarized substrate WF (FIG. 9(f)). The example illustrated in FIG. 9 uses the protective layer 106. If the substrate including the convex portions 100 and the concave portions 102 as illustrated in FIG. 9(a) are directly polished, for example, by the CMP, the concave portions 102 are sometimes polished at the same time together with the convex portions 100. To prevent the concave portions 102 from being polished, the example illustrated in FIG. 9 uses the protective layer 106 to selectively remove the convex portions 100. The reaction layer 104 is equivalent to the one mentioned in the example of FIG. 8. The protective layer 106 has to contribute to reduction of the rate of polishing the concave portions 102 even though polishing pressure difference is small in the concave and convex portions due to small difference in irregularities of the protective layer 106. It is then desired that: (1) polishing rate have high dependence on polishing pressure, and (2) the rate of polishing the protective layer 106 be lower than that of polishing the reaction layer. Possible materials for the protective layer 106 are, for example, so-called corrosion inhibitors, resists, SOGs, etc. The corrosion inhibitors include benzotriazole, benzotriazole derivative, indole, 2-ethylimidazole, benzimidazole, 2-mercaptobenzimidazole, 3-amino-1,2,4-triazole, 3-amino-5methyl-4H-1,2,4-triazole, 5-amino-1H-tetrazole, 2-mercaptobenzothiazole, sodium 2-mercaptobenzothiazole, 2-methylbenzothiazole, (2-benzothiazolylthio) acetic acid, 3-(2-benzothiazolylthio) propionic acid, 2-mercapto-2-thiazoline, 2-mercaptobenzoxazole, 2,5-dimercapto-1,3,4-thiadiazole, 5-methyl-1,3,4--thiadiazole-2-thiol, 5-amino-1,3,4-thiadiazole-2-thiol, pyridine, fenadine, acridine, 1-hydroxypyridine-2-thione, 2-aminopyridine, 2-aminopyrimidine, trithiocyanuric acid, 2-dibutylamino-4,6-dimercapto-s-triazine, 2-anilino-4,6-dimercapto-s-triazine, 6-aminopurine, 6-thioguanine, and one or more kinds selected from a group consisting of combinations of these corrosion inhibitors. A method of forming the protective layer 106 made of a resist or a SOG may be to form a film by performing spin coating or the like in a separate chamber. The protective layer 106 made of the corrosion inhibitor may be formed by bringing the substrate WF into contact with a solution bath for forming the protective layer, which is installed separately from the reaction solution bath 600, as discussed with reference to FIG. 4. The protective layer 106 may be formed by another method similar to the forming method of the reaction layer, which is illustrated in FIGS. 2 and 3. In consideration of prevention of contamination with components of the reaction layer, the prevention is more reliably achieved if the polishing removal of the protective layer 106 is performed on a different polishing table than the table used in the polishing removal of the reaction layer 104. As to the polishing removal of the reaction layer 104 using the substrate polishing apparatus 300, it is ideal to remove only the reaction layer 104. The polishing rate as in the common CMP is therefore unnecessary, and the polishing rate is preferably, for example, 10 nm/min or less. Since planarization also has to be performed, the contact between the polishing pad 310 and the substrate WF needs to be controlled more than in the common CMP. Therefore, the contact pressure of the polishing pad 310 with respect to irregularities in the surface of the to-be-removed material of the substrate WF is preferably highly selective. The contact pressure of the polishing pad 310 relative to the irregularities in the surface of the to-be-removed material of the substrate WF is preferably highly selective. As a polishing condition, for example, a smaller polishing pressure is more favorable. The polishing pressure is preferably 1 psi or less, and more preferably, 0.1 psi or less. The surface of the polishing pad 310 may be smoothed through adjustment of dressing conditions and the like or may be cooled to be increased in rigidity. In order to prevent the abrasive particles contained in the processing solution from causing damage to the under layer (unreacted layer) of the reaction layer 104 after the brittle reaction layer 104 on the substrate WF is removed, it is preferable that the processing solution contain only abrasive particle components and that an abrasive particle size be 20 nm or less to decrease a removal unit. The abrasive particle concentration may be reduced without decreasing the uniformity of the polishing amount within the surface of the substrate WF. Since pH is associated with the adsorption of abrasive particles to the surface and the clumping of abrasive particles themselves, the pH may be properly conditioned using the pH conditioning agent. The foregoing is an example of the polishing removal of the reaction layer 104 using abrasive particles. If the reaction layer 104 is sufficiently brittle, the substrate may be polished by pressing the polishing pad 310 against the surface of the substrate WF in the presence of pure water only.

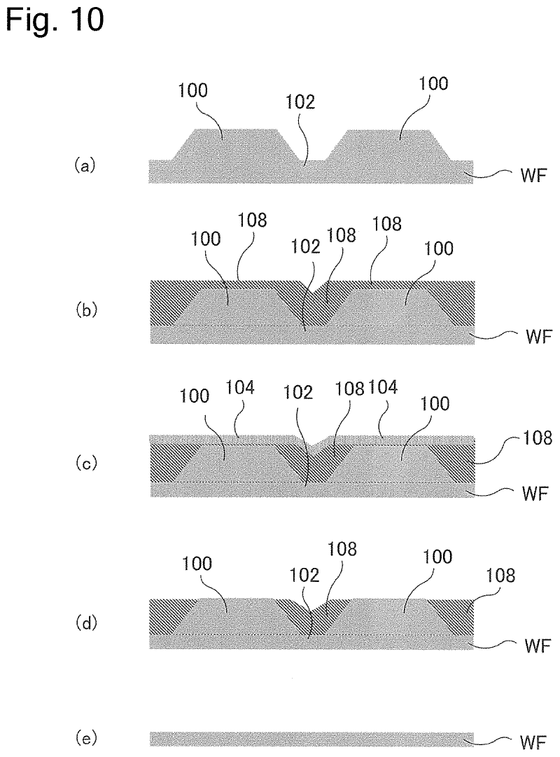

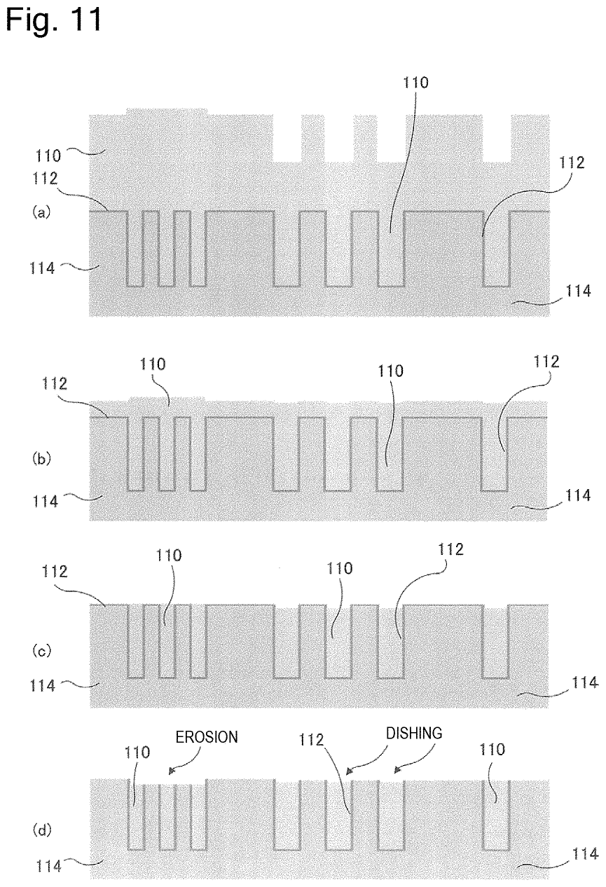

FIG. 10 show an example of substrate planarization by polishing according to one embodiment. Like the example illustrated in FIG. 8, FIG. 10 show the example of planarization of the substrate including the convex portions 100 and the concave portions 102. FIG. 10(a) shows the initial state of the to-be-removed layer formed on the substrate surface from a lateral view. As an example, the convex portions 100 are of a nanometer-level size. In the example illustrated in FIG. 10, a sacrifice layer 108 is initially formed on the entire surface of the substrate WF (FIG. 10(b)). The sacrifice layer 108 preferably allows the reaction layer 104 to be formed in the same manner as the convex portions 100 which are the removal objects. The sacrifice layer 108 further preferably makes it possible to achieve the equal removal rate to the convex portions 100 which are the removal objects. After the formation of the sacrifice layer 108, the reaction layer 104 is formed in the entire surface of the sacrifice layer 108 (FIG. 10(c)). The reaction layer 104 is preferably formed with a thickness of an atomic layer unit on a several A level. The reaction layer 104 may be formed by any of the above-discussed apparatuses and methods. After the reaction layer 104 is formed, only the reaction layer 104 is removed (FIG. 10(d)). The reaction layer 104 can be removed using the above-discussed substrate polishing apparatus 300 or catalyst-referred etching (CARE). The formation and removal of the reaction layer 104 are repeated, to thereby remove the convex portions 100 of the substrate WF and obtain a planarized substrate WF (FIG. 10(e)). The example illustrated in FIG. 10 uses the sacrifice layer 108. If the substrate with the convex portions 100 and the concave portions 102 as illustrated in FIG. 10(a) is polished, for example, directly by the CMP or the like, the concave portions 102 are sometimes polished together with the convex portions 100. To avoid such a problem, the example illustrated in FIG. 10 performs planarization using the sacrifice layer 108 so that the concave portions 102 are not polished, whereby the convex portions 100 and the sacrifice layer 108 are equalized in selectivity of polishing rate. The reaction layer 104 is equivalent to the one mentioned in the example of FIG. 8. It is desired that, in the case of the to-be-removed layer with a structure shown in FIG. 10, the sacrifice layer 108 allow the reaction layer 104 to be formed in the same manner as the to-be-removed layer and/or make it possible to obtain the reaction layer polished at the same polishing rate as the to-be-removed layer. However, to eliminate a convex shape, such as a wide convex shape, which is difficult to be eliminated in CMP planarization (which is small in roughness elimination efficiency), the convex shape may be positively eliminated, for example, by setting the rate of polishing the sacrifice layer equal to or less than the rate of polishing the to-be-removed layer. The sacrifice layer 108 is, for example, an organic-based material such as a resist, a SOG and the like. It is possible to form films of the foregoing materials by spin coating or the like. A film formed by a film-forming method such as CVD performed in a separate chamber is also adoptable as the sacrifice layer 108 as long as the film is made of a material which satisfies the above-mentioned conditions. A material contained in the to-be-removed layer may be used as the sacrifice layer 108. If the to-be-removed material comprises a plurality of to-be-removed materials as illustrated in the example of planarization of copper interconnects shown in FIG. 11 mentioned later, the sacrifice layer 108 may be formed so as to cover the whole. However, the sacrifice layer 108 may be formed, for example, only on the copper interconnects only on a specific to-be-removed material by non-electrolytic plating or the like. Timing for forming the sacrifice layer 108 is explained with reference to an example of planarization of copper interconnects. FIG. 11 show an example of a planarization process in embedment of copper interconnects through CMP. The planarization process first removes excess copper of a copper layer 110 formed by electrolytic plating for the purpose of common interconnect embedment (processes illustrated in FIGS. 11(a), 11(b) and 11(c)). A under layer, namely, barrier metal 112 (which is intended to prevent distribution of the copper layer 110 into an insulation layer 114) is further removed to eventually leave copper only in an interconnect part (processes illustrated in FIGS. 11(c) and 11(d)). A surface of the copper layer 110 subjected to the electrolytic plating has irregularities attributed to width of interconnect trenches formed in the under layer and plating conditions. It is difficult to completely eliminate the irregularities simply by the common CMP, depending on size of convex and concave shapes of the irregularities. This leads to generation of so-called dishing caused by excessive polishing of copper interconnects, and so-called erosion caused by overpolishing of the insulation layer (see FIG. 11(d)), and thus incurs uneven height of the interconnects. The sacrifice layer 108 is formed to reduce an effect of the convex and concave shapes. Timing for forming the sacrifice layer 108 may be: (a) prior to polishing (after the formation of the copper layer), (b) some point during the polishing of the copper layer (immediately before the removal of the copper layer on the barrier metal), or (c) after the removal of the copper layer on the barrier metal, as illustrated in FIG. 11. In view of planarization achieved by the formation and removal of the reaction layer on the atomic layer level, it is preferable that the sacrifice layer 108 be formed at the timing (b) or (c). For example, if the sacrifice layer 108 is formed at the timing (b), the dishing can be prevented, which is caused by planarization of convex portions of the copper layer 110. If the sacrifice layer 108 is formed at the timing (c), it is possible to reduce the rate of polishing the copper in a dished portion, that is, the progress of the dishing at the time of the subsequent removal of the barrier metal 112. The sacrifice layer 108 may be different between the timings (b) and (c). For example, at the timing (b), the convex shape may be positively eliminated by setting the polishing rate of the sacrifice layer 108 equal to or less than the copper layer 110. As to the timing (c), if dishing is suppressed from occurring at the timing (b), the sacrifice layer 108, the copper layer 110, and the insulation layer 114 are preferably equal in polishing rate. When the substrate polishing apparatus 300 performs the polishing removal of the reaction layer 104, it is ideal to remove only the reaction layer 104. This eliminates the necessity of the polishing rate as in the common CMP. It is then desired that the polishing rate be, for example, 10 nm/min or less. Since planarization also has to be performed, the contact between the polishing pad 310 and the substrate WF needs to be controlled more than in the common CMP. Contact pressure of the polishing pad 310 with respect to the irregularities on the surface of the to-be-removed material of the substrate WF is preferably highly selective. For example, as a polishing condition, a smaller polishing pressure is more favorable. The polishing pressure is preferably 1 psi or less, or more preferably, 0.1 psi or less. The surface of the polishing pad 310 may be increased in rigidity by being smoothed through adjustment of dressing conditions and the like or may be cooled. In order to prevent the abrasive particles in the processing solution from causing damage to the under layer (unreacted layer) of the reaction layer 104 after the removal of the brittle reaction layer 104 on the substrate WF, it is preferable, for example, that the polishing processing solution contain only abrasive particle components, and that an abrasive particle size be as small as 20 nm or less to reduce the removal unit. The abrasive particle concentration may also be reduced without decreasing the uniformity of polishing amount within the surface of the substrate WF. The pH is associated with adsorption of the abrasive particles to the surface and clumping of the abrasive particles themselves, so that the pH may be properly conditioned using a pH conditioning agent. The foregoing description explains the example of polishing removal of the reaction layer 104 using the abrasive particles. If the reaction layer 104 is sufficiently brittle, the substrate may be polished by pressing the polishing pad 310 against the surface of the substrate WF in the presence of pure water only.

The embodiments of the invention have been described with reference to several examples. The embodiments of the invention are presented to facilitate the understanding of the invention and do not limit the invention. The invention may be modified or improved without deviating from the gist thereof. Needless to say, the invention includes equivalents thereof. The constituent elements mentioned in the claims and description may be combined in any ways or omitted within a scope where the problem can be at least partially solved or a scope where the advantages are at least partially provided.

### REFERENCE SIGN LIST

100 convex portion
102 concave portion
104 reaction layer
106 protective layer
108 sacrifice layer
300 substrate polishing apparatus
310 polishing pad
320 polishing table
330 top ring
340 processing solution supply nozzle
400 arm
502 liquid source
504 mixer
506 sensor
600 reaction solution bath
650 electrolyte solution bath
652 opposite electrode
654 electric power source
656 feed pin
900 control unit
312a through-hole
342a outlet
500A processing solution supply line
500B processing solution supply line
WF substrate

What is claimed is:

1. A method of chemical mechanical polishing of a substrate, comprising the steps of:
polishing the substrate using a processing solution, and
changing concentration of an effective component in the processing solution, which contributes to the polishing of the substrate.

2. The method according to claim 1,
wherein the effective component in the processing solution contains at least one of (1) a component that oxidizes a layer to be polished of the substrate, (2) a component that dissolves the layer to be polished of the substrate, and (3) a component that exfoliates the layer to be polished of the substrate.

3. The method according to claim 1, further comprising:
the step of measuring thickness of the layer to be polished of the substrate,
wherein, based on the measured thickness of the layer to be polished of the substrate, the concentration of the effective component in the processing solution is changed.

4. The method according to claim 1, further comprising:
the step of measuring pH of the processing solution,
wherein, based on the measured pH of the processing solution, the concentration of the effective component in the processing solution is changed.

5. The method according to claim 1,
wherein the processing solution contains abrasive particles,
the method comprising the step of measuring abrasive particle concentration in the processing solution,
wherein, based on the measured abrasive particle concentration, the concentration of the effective component in the processing solution is changed.

6. The method according to claim 1,
wherein the concentration of the effective component in the processing solution is changed by attenuating the processing solution with pure water.

7. The method according to claim 1,
wherein the processing solution contains an oxidizing component, and
wherein the concentration of the oxidizing component in the processing solution is effectively changed by adding a reductant for reducing an oxidation effect of the processing solution.

8. The method according to claim 1,
wherein the processing solution contains acid as a dissolution component, and
wherein the concentration of the dissolution component is changed by adding an alkaline agent into the processing solution.

9. The method according to claim 1,
wherein the processing solution contains alkali as a dissolution component, and
wherein the concentration of the dissolution component is changed by adding acid into the processing solution.

10. A method of chemical mechanical polishing of a substrate, comprising the steps of:
polishing the substrate using a processing solution, and
changing temperature of the processing solution during the polishing of the substrate.

11. The method according to claim 10, further comprising:
the step of measuring thickness of a layer to be polished of the substrate,
wherein, based on the measured thickness of the layer to be polished of the substrate, the temperature of the processing solution is changed.

12. A method of chemical mechanical polishing of a plurality of substrates of the same kind, comprising the steps of:
polishing a first substrate using a first processing solution, and
polishing a second substrate using a second processing solution
wherein the second processing solution differs from the first processing solution in concentration of an effective component contained in the processing solution, which contributes to the polishing of the substrate.

13. A method for removing a metal layer formed on a substrate, comprising the steps of:
intermittently supplying the metal layer of the substrate with an oxidizing agent and/or a complexation agent and thus forming a brittle reaction layer on a surface of the metal layer, and
polishing and removing the brittle reaction layer with a pad pressed against the brittle reaction layer in the presence of the processing solution.

14. The method according to claim 13, further comprising:
the step of polishing the substrate with the pad pressed against the substrate in the presence of pure water.

15. The method according to claim 13, comprising:
the step of supplying the oxidizing agent and/or the complexation agent onto the pad while the substrate and the pad are out of contact with each other, and then bringing the substrate and the pad into contact with each other.

16. The method according to claim 13, comprising:
the step of intermittently supplying the oxidizing agent and/or the complexation agent from direction of the pad toward the substrate.

17. The method according to claim 16, comprising the steps of:
supplying a first processing solution containing an oxidizing agent and/or a complexation agent from direction of the pad toward the substrate, and
supplying a second processing solution containing a different component from the first processing solution from above the pad toward the pad.

18. The method according to claim 17,
wherein the processing solution contains a reductant.

19. A method for removing a metal layer formed on a substrate, comprising the steps of:
supplying an electrolyte solution to the metal layer of the substrate,
supplying electric current to the metal layer of the substrate through the electrolyte solution, and
polishing the substrate with a pad pressed against the substrate.

20. The method according to claim 13, comprising:
the step of changing a supply amount of the oxidizing agent and/or the complexation agent during the removal of the metal layer.

21. The method according to claim 19, comprising:
the step of changing a magnitude of the electric current that is supplied to the substrate during the polishing of the substrate.

22. The method according to claim 13, comprising:
the step of changing a duration when the pad is pressed against the substrate during the removal of the metal layer.

23. The method according to claim 13,
wherein the metal layer includes at least one from a group consisting of aluminum, tungsten, copper, ruthenium, and cobalt.

24. A method for removing a silicon dioxide layer that is formed on a substrate, comprising the steps:
supplying an adsorptive surface-active agent to the silicon dioxide layer and thus forming a protective layer on a surface of the silicon dioxide layer,
polishing the protective layer with a pad pressed against the protective layer in the presence of a processing solution and thus removing the silicon dioxide layer, and
intermittently supplying the pad with an additive that facilitates adsorption of abrasive particles onto the pad.
